(19) United States
(12) Patent Application Publication
(10) Pub. No.: US 2025/0306092 A1
(43) Pub. Date: Oct. 2, 2025

(54) WAFER INSPECTION APPARATUS, CHUCK POSITION MEASUREMENT METHOD, AND TARGET

(71) Applicant: TOKYO SEIMITSU CO., LTD., Tokyo (JP)

(72) Inventors: Hiroo TAMURA, Hachioji-shi (JP); Kota TERAKAWA, Hachioji-shi (JP)

(21) Appl. No.: 19/091,543

(22) Filed: Mar. 26, 2025

(30) Foreign Application Priority Data
Mar. 27, 2024 (JP) 2024-051336

(51) Int. Cl. G01R 31/28; G01R 1/073

(52) U.S. Cl. CPC G01R 31/2891; G01R 1/07342

(57) ABSTRACT

A wafer inspection apparatus, a chuck position measurement method, and a target capable of improving a throughput are provided. A wafer inspection apparatus 10 includes a probe card 21, a chuck 22 capable of electrically connecting a wafer W to the probe card 21, a holding portion 23 holding the chuck 22, a target provided on the chuck 22, and an imaging unit 25 imaging the target. The target is formed to be larger than an allowable movement range of the chuck 22 with respect to the holding portion 23 to be able to be imaged with the imaging unit 25 fixed at a predetermined position. A position and an angle of the chuck 22 are determined on the basis of the imaged target.

### BACKGROUND OF THE INVENTION

### Field of the Invention

The present disclosure relates to a wafer inspection apparatus, a chuck position measurement method, and a target.

### Description of Related Art

A multi-probing apparatus including a test head used for wafer measurement and a head stage to which a probe card for conducting electrical signals to a wafer is attached, and in which a chuck holding the wafer is detachably supported by an aligner, and the chuck can be brought into contact with the probe card of the head stage by the aligner, is known. According to the multi-probing apparatus, a plurality of measurement chambers are provided and the chuck is attachable to and detachable from the head stage by the aligner, thereby making it possible to simultaneously inspect a plurality of wafers (see, for example, Patent Document 1).

Here, in an idle state of the chuck in which power is cut off due to, for example, maintenance, an emergency power shutdown, or the like, the chuck is held by a holding portion provided on the head stage. When the held chuck is received by the aligner, a mark on a rear surface of the chuck is detected by an imaging unit, and a receiving position of the aligner is corrected.

### Patent Documents

[Patent Document 1] Japanese Unexamined Patent Application, First Publication No. 2016-54318

### SUMMARY OF THE INVENTION

Here, for example, the mark is formed as a small-diameter hole that can be imaged by the imaging unit. Therefore, if the chuck held by the holding portion is significantly displaced beyond an imaging range (field of view) of the imaging portion, the mark will also be significantly displaced along with the chuck. Therefore, it is necessary to detect the mark by scanning a movement range of the chuck with the imaging unit. Therefore, it takes time to detect the mark, and there is still room for improvement from the perspective of throughput.

The present disclosure has been made in view of the above circumstances, and an objective of the present disclosure is to provide a wafer inspection apparatus, a chuck position measurement method, and a target capable of achieving an improvement in throughput.

In order to solve the above-described problems, the present disclosure provides the following methods.
<1> A wafer inspection apparatus according to one aspect of the present disclosure includes a probe card provided on a head stage, a chuck holding a wafer and being able to electrically connect the wafer to the probe card, a holding portion provided below the head stage and holding the chuck, a target provided on the chuck, and an imaging unit imaging the target, in which the target is formed to be larger than an allowable movement range of the chuck with respect to the holding portion to be able to be imaged by the imaging unit with the imaging unit fixed at a predetermined position, and a position and angle of the chuck are determined on the basis of the target imaged by the imaging unit.

According to the wafer inspection apparatus, the target is formed to be larger than the allowable movement range of the chuck with respect to the holding portion. Therefore, with the imaging unit fixed at a predetermined position, the target can be imaged in a single shot without being scanned by the imaging unit. The position and angle of the chuck can be determined on the basis of the target imaged by the imaging unit. Thereby, an improvement in throughput can be achieved.
<2> In the wafer inspection apparatus according to the above described <1>, the target may be provided on an imaged portion formed of a sheet material which is a separate member from the chuck, and may have a plurality of marks having holes with diameters of 0.3 to 7 mm at a pitch of 1 mm.

According to the wafer inspection apparatus, the imaged portion is provided on the chuck. The imaged portion is a separate member from the chuck. Therefore, cost reduction can be achieved compared to when, for example, the target is directly provided on the chuck.

Also, the target has the plurality of marks. Therefore, when a disposition and shape of the plurality of marks are set so that the position and angle of the chuck can be measured, the position and angle of the chuck can be determined on the basis of the marks imaged by the imaging unit. Thereby, an improvement in throughput can be achieved.
<3> In the wafer inspection apparatus according to the above-described <2>, the imaged portion may have an ensured reflectance on an imaged surface and may be provided with a black Mylar sheet on a side opposite to the imaged surface.

According to the wafer inspection apparatus, the reflectance of the imaged surface is ensured in the imaged portion. Also, the black Mylar sheet is provided on a side opposite to the imaged surface. Therefore, the marks can be reliably imaged by the imaging unit.
<4> A chuck position measurement method according to one aspect of the present disclosure is a chuck position measurement method in which a chuck is held by a holding portion, and a target provided on the chuck is imaged by the imaging unit, and the chuck position measurement method includes imaging the target, which is formed to be larger than an allowable movement range of the chuck with respect to the holding portion, in a single shot with the imaging unit fixed to a predetermined position, and determining a position and an angle of the chuck on the basis of the target imaged by the imaging unit.

According to the chuck position measurement method, the target is formed to be larger than the allowable movement range of the chuck with respect to the holding portion. Therefore, with the imaging unit fixed at a predetermined position, the target can be imaged in a single shot without being scanned by the imaging unit. The position and angle of the chuck can be determined on the basis of the target imaged by the imaging unit. Thereby, an improvement in throughput can be achieved.
<5> A target according to one aspect of the present disclosure is a target imaged by an imaging unit to determine a position and an angle of a chuck held by a holding portion, with the chuck held by the holding portion, is formed to be larger than an allowable movement range of the chuck with respect to the holding portion to be able to be imaged by the imaging unit with the imaging unit fixed at a predetermined position, and has a plurality of marks whose disposition and shape are set to be able to measure a position and an angle of the chuck.

According to the target, the target is formed to be larger than the allowable movement range of the chuck with respect to the holding portion. Also, the target has the plurality of marks, and the disposition and shape of the plurality of marks are set so that the position and angle of the chuck can be measured. Therefore, with the imaging unit fixed at a predetermined position, the target can be imaged in a single shot without being scanned by the imaging unit. The position and angle of the chuck can be determined on the basis of the marks imaged by the imaging unit. Thereby, an improvement in throughput can be achieved.

According to the present disclosure, the throughput can be improved.

### BRIEF DESCRIPTION OF THE DRAWINGS

FIG. 1 is a conceptual view illustrating a wafer inspection apparatus provided in a multi-probing apparatus according to an embodiment of the present disclosure.

FIG. 2 is a perspective view illustrating an aligner provided in the multi-probing apparatus according to the embodiment.

FIG. 3 is a perspective view of a chuck provided on a head stage according to the embodiment from below.

FIG. 4 is a rear view illustrating a movement restriction portion provided in the chuck according to the embodiment.

FIG. 5 is a perspective view illustrating an imaged portion attached to the chuck according to the embodiment.

FIG. 6 is a plan view illustrating the imaged portion of FIG. 5.

FIG. 7 is a conceptual view for explaining a disposition and shape of a target according to the embodiment.

FIGS. 8(a) to 8(d) are conceptual views illustrating a minimum configuration for an imaging unit to capture an image in a single shot and determine a position.

FIG. 9 is a plan view illustrating an example in which the target according to the embodiment is used for teaching.

FIG. 10 is a rear view of a chuck of a comparative example from below.

FIG. 11 is a plan view illustrating an imaged portion of modified example 1.

FIG. 12 is a plan view illustrating an imaged portion of modified example 2.

### DETAILED DESCRIPTION OF THE INVENTION

Hereinafter, a wafer inspection apparatus, a chuck position measurement method, and a target according to one embodiment of the present disclosure will be described with reference to the drawings. Further, in the following embodiment, when referring to a number of components, a numerical value, an amount, a range, or the like, unless otherwise explicitly stated or clearly limited in principle to a specific number, they are not limited to that specific number and may refer to the specific number or more or the specific number or less.

Also, when referring to a shape or positional relationship of components or the like, unless otherwise explicitly specified or considered in principle to be clearly not the case, the present disclosure includes those that are substantially approximate or similar in shape or the like.

Also, the drawings may be exaggerated, such as by enlarging characteristic portions, to make the features easier to understand, and dimensional ratios or the like of the components may not be the same as actual ones. Also, in cross-sectional views, hatching for some components may be omitted to make the cross-sectional structure of the components easier to understand.

### <Multi-Probing Apparatus>

FIG. 1 is a conceptual view illustrating a (single) wafer inspection apparatus 10 of a multi-probing apparatus.

As illustrated in FIG. 1, the wafer inspection apparatus 10 includes, for example, a housing 2, a plurality of test heads 3, and an aligner (X-Y-Z axis unit) 4.

The housing 2 includes, for example, a plurality of head stages 12. The head stage 12 has, for example, mounting holes 14 provided at intervals in a longitudinal direction of the housing 2. A probe card 21 to be described later is attached to the mounting hole 14. The plurality of test heads 3 are provided above the head stage 12. The test head 3 is electrically connected to the probe card 21 to be described later.

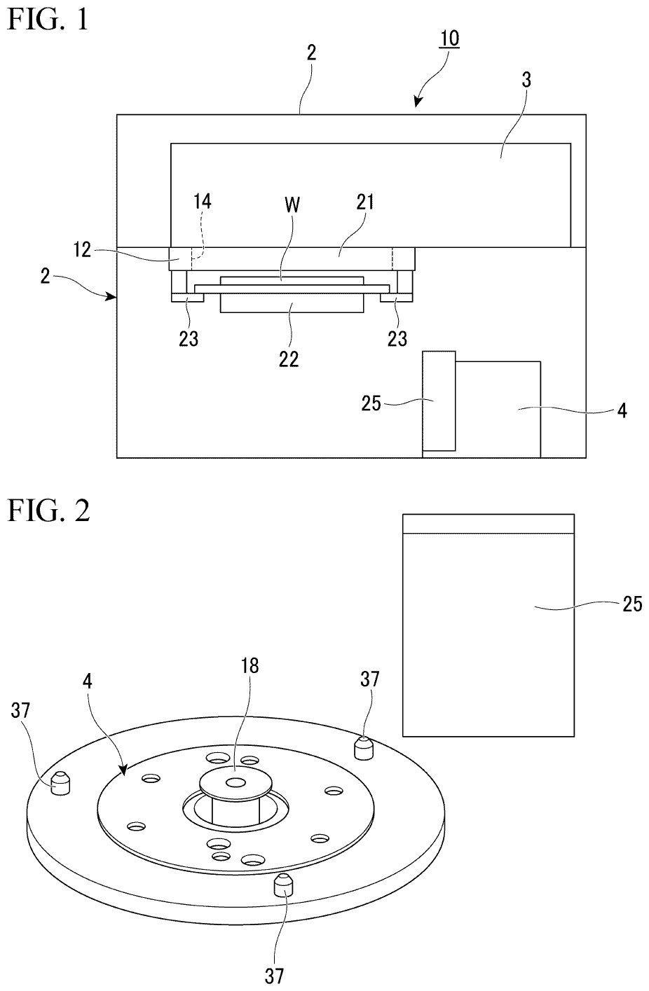

FIG. 2 is a perspective view illustrating an aligner provided in the multi-probing apparatus.

As illustrated in FIGS. 1 and 2, the aligner 4 is provided below the head stage 12. The aligner 4 is movable in X-Y-Z positional directions and in a direction of angle T. The aligner 4 includes a Z axis 18 that is movable in the Z positional direction and in the direction of angle T. The aligner 4 detachably supports a chuck 22 (to be described later) by, for example, vacuum suction or mechanical means. The aligner 4, while detachably supporting the chuck 22, electrically connects each chip of a wafer W held by the chuck 22 to the probe card 21, and inspects each chip with the test head 3.

### <Wafer Inspection Apparatus>

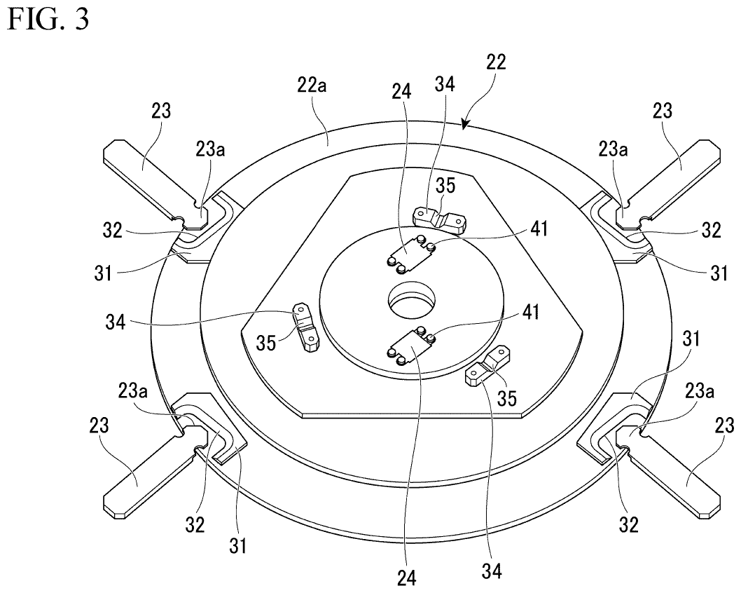

FIG. 3 is a perspective view of the chuck provided on the head stage, from below.

As illustrated in FIGS. 1 to 3, the plurality of head stages 12 include the probe card 21, the chuck 22, a holding portion (preventing falling off of the chuck) 23, and an imaged portion 24. Also, the wafer inspection apparatus 10 includes an imaging unit 25 that is shared by one multi-probing apparatus.

The probe card 21 is attached to the mounting hole 14 of the head stage 12 and is disposed below the test head 3. The probe card 21 is electrically connected to the test head 3. The probe card 21 is configured to be electrically connectable to electrodes of each chip formed on the wafer W (both not illustrated). With the electrodes of each chip on the wafer W electrically connected to the probe card 21, each chip on the wafer Wis inspected by the test head 3.

The chuck 22 adsorbs and holds the wafer W by, for example, vacuum suction or the like. The chuck 22 is detachably supported by the aligner 4 and is movable in the X-Y-Z positional directions and the direction of angle T by the aligner 4. The chuck 22, while holding the wafer W, can electrically connect the chip to the probe card 21 provided on the head stage 12. The chuck 22 is held by the holding portion 23 to be described later in a state in which power is cut off due to, for example, maintenance, an emergency power shutdown, or the like.

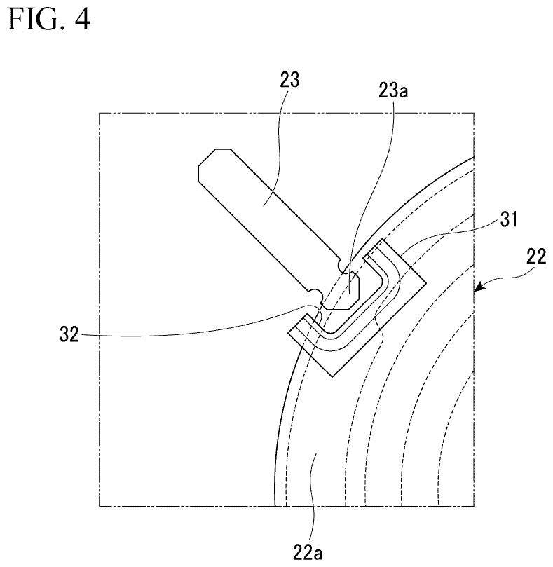

FIG. 4 is a rear view illustrating a movement restriction portion provided on the chuck.

As illustrated in FIGS. 3 and 4, the chuck 22 includes a plurality of (four in the embodiment) movement restriction portions 31 around a rear surface 22a. The movement restriction portions 31 are provided around the rear surface 22a at predetermined intervals in a circumferential direction of the chuck 22. Each of the movement restriction portions 31 is formed in a U shape and has a recessed portion 32 that opens outward in a radial direction of the chuck 22. A distal end 23a of the holding portion 23 to be described later is disposed in the recessed portion 32. In the embodiment, four movement restriction portions 31 are described as an example of the plurality of movement restriction portions 31, but the number of movement restriction portions 31 can be selected arbitrarily.

As illustrated in FIG. 3, the chuck 22 includes a plurality of (three in the embodiment) receiving portions 34 around the rear surface 22a. A kinematic pin 37 fits into a recessed portion 35 of the receiving portion 34. As illustrated in FIG. 2, the kinematic pin 37 is provided on the aligner 4. The kinematic pin 37 engages with the recessed portion 32 of the receiving portion 34, and thereby the chuck 22 is supported in a positioned state on the aligner 4.

As illustrated in FIGS. 1, 3, and 4, the holding portion 23 is provided below the head stage 12. The holding portion 23 holds the chuck 22 in a state in which power is cut off due to maintenance, an emergency power shutdown, or the like. Specifically, the plurality of holding portions 23 are disposed at around the mounting holes 14 of the head stage 12 at predetermined intervals in the circumferential direction of the chuck 22. In the embodiment, an example in which the plurality of (four) holding portions 23 are provided around the mounting holes 14 at intervals of 90 degrees is described, but the present disclosure is not limited thereto.

The plurality of holding portions 23 are disposed in the radial direction of the chuck 22 and are provided to be movable in the radial direction to approach and move away from each other with the mounting holes 14 as a center. The plurality of holding portions 23 hold the chuck 22 in a state in which they are disposed close to each other in the radial direction. On the other hand, the plurality of holding portions 23 allow the chuck 22 to be supplied and collected by the aligner 4 in a state in which they are disposed apart from each other in the radial direction.

As illustrated in FIGS. 3 and 4, the holding portion 23 restricts a movement range of the chuck 22 using the movement restriction portion 31 in a state in which the chuck 22 is held. Specifically, with the chuck 22 held, the distal end 23a of the holding portion 23 is disposed in the recessed portion 32 of the movement restriction portion 31. Therefore, when the distal end 23a of the holding portion 23 comes into contact with the recessed portion 32 of the movement restriction portion 31, the movement range of the chuck 22 is restricted. Hereinafter, the movement range of the chuck 22 restricted by the recessed portion 32 of the movement restriction portion 31 may be referred to as a “allowable movement range of the chuck 22” with respect to the holding portion 23.

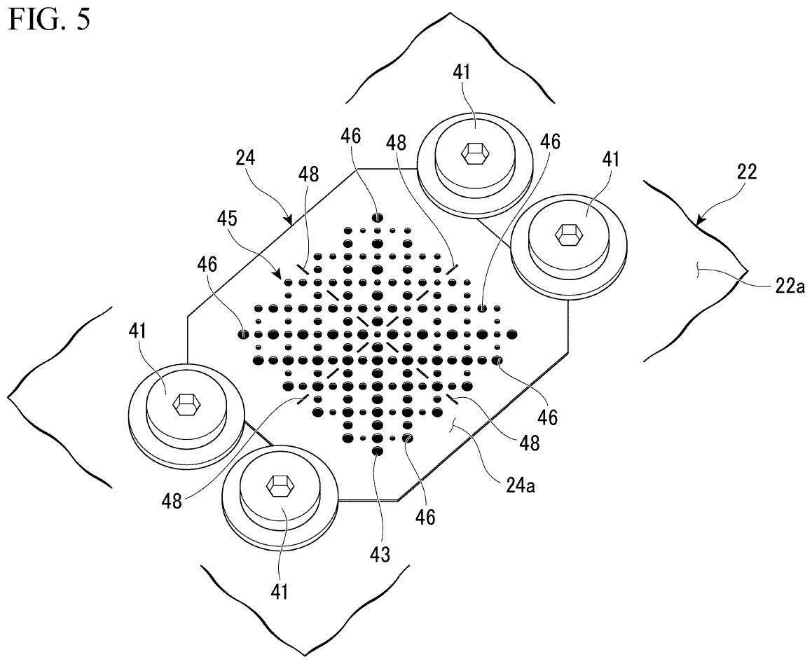

FIG. 5 is a perspective view illustrating an imaged portion attached to the chuck. As illustrated in FIGS. 3 and 5, for example, two imaged portions 24 are provided symmetrically about a center of the chuck 22 on the rear surface 22a of the chuck 22. In the embodiment, an example in which two imaged portions 24 are provided on the rear surface 22a of the chuck 22 is described, but one imaged portion 24 may be provided at the center of the chuck 22 or at a position other than the center on the rear surface 22a of the chuck 22. The imaged portion 24 is formed, for example, in a rectangular shape with four chamfered corners. The imaged portion 24 is not limited to a rectangular shape, and can be formed in any shape.

The imaged portion 24 is formed as, for example, a separate member from the chuck 22. The imaged portion 24 is detachably fixed to the rear surface 22a of the chuck 22 by a fixing member such as a bolt 41. The imaged portion 24 is formed of, for example, a translucent sheet material with a plate thickness of 0.3 mm. A reflectance of an imaged surface 24a of the imaged portion 24 is ensured by, for example, electrolytic polishing. The imaged portion 24 has a black Mylar sheet 43 provided on, for example, a side opposite to the imaged surface 24a.

As illustrated in FIG. 5, the imaged portion 24 has a target 45. The target 45 is formed to be larger than the allowable movement range of the chuck 22. The target 45 has a plurality of marks 46. When the target 45 is formed to be larger than the allowable movement range of the chuck 22 and has the plurality of marks 46, the plurality of marks 46 can be held within an imaging range of the imaging unit 25 to be described below.

That is, the plurality of marks 46 are provided at positions in which they can be imaged in a state in which the imaging unit 25 to be described late is fixed at a predetermined position. Therefore, among the plurality of marks 46, the marks 46 necessary for measuring a position and angle of the chuck 22 can be imaged (detected) in a single shot by the imaging unit 25.

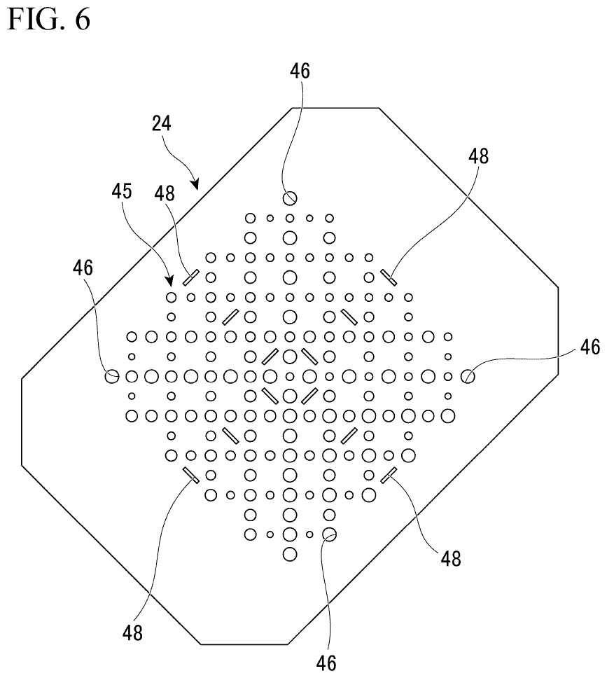

Further, the imaged portion 24 may have, for example, a slit 48 formed radially. When the imaged portion 24 has the slit 48, a center of the imaged portion 24 can be easily confirmed through the slit 48. Thereby, teaching to be described later is made easier. An orientation of the slit 48 can be selected arbitrarily. For example, the slit 48 may be provided to intersect (be orthogonal to) a straight line extending in the radial direction (see FIG. 6).

In the embodiment, an example in which the imaged portion 24 is formed as a separate member from the chuck 22 and the marks 46 are provided on the imaged portion 24 is described, but the target 45 may be provided directly on the chuck 22. The marks 46 are formed on the imaged portion 24 by, for example, etching, laser processing, laser marking, cutting machining, or the like.

As illustrated in FIGS. 1 and 2, the imaging unit 25 is capable of imaging the target 45 while being fixed at a predetermined position. As the imaging unit 25, for example, a needle alignment camera (needle alignment microscope) is used. An imaging range (field of view) of the imaging unit 25 is relatively small, for example, about 3 mm×3 mm or 3 mm×4 mm.

The imaging unit 25 images (detects) the marks 46 of the target 45. The X-Y-Z position and angle T of the chuck 22 are determined on the basis of the marks 46 imaged by the imaging unit 25. A receiving position of the aligner 4 is corrected on the basis of the determined X-Y-Z positions and angle T of the chuck.

### <Mark>

Next, the mark 46 of the target 45 will be described with reference to FIG. 6 to FIG. 6 is a plan view illustrating the imaged portion of FIG. 5.

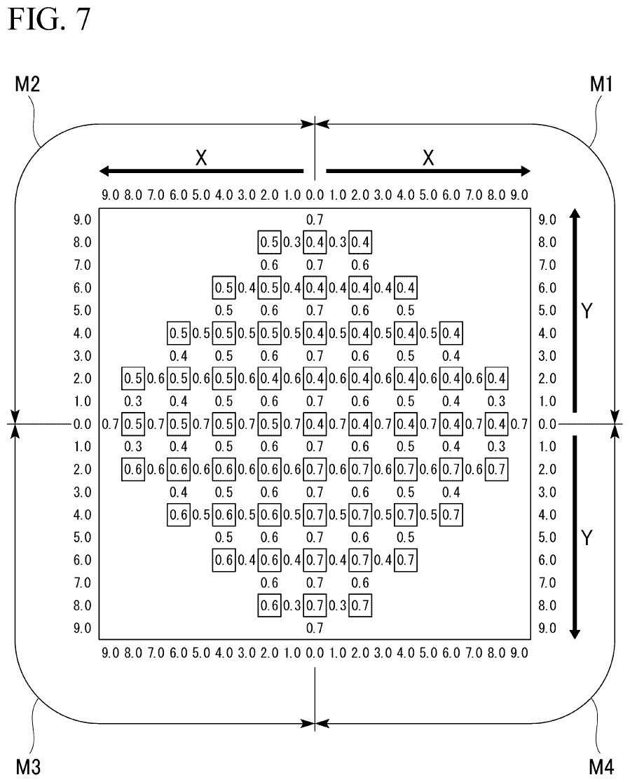

FIG. 7 is a conceptual view illustrating a disposition and a shape of the target. In FIG. 7, the horizontal axis indicates a pitch in the X direction. The vertical axis indicates a pitch in the Y direction. The numerical values 0.3 to 0.7 indicate diameters of the marks 46.

As illustrated in FIGS. 1, 6, and 7, the marks 46 imaged by the imaging unit 25 preferably have, for example, a circular shape that is easy to detect by the imaging unit 25. Since an imaging range of the imaging unit 25 is, for example, 3 mm×3 mm or 3 mm×4 mm, the mark 46 is preferably a circle having a diameter of 0.3 mm to 0.7 mm. Disposition of the marks 46 is determined under the following conditions so that the marks 46 form a unique pattern. The marks 46 are provided at lattice points with a pitch of 1 mm (0 mm, ±1.0 mm . . . ±9.0 mm) in the X direction. Also, the marks 46 are provided at lattice points with a pitch of 1 mm (0 mm, ±1.0 mm . . . ±9.0 mm) in the Y direction.

Specifically, the target 45 has the marks 46 with a diameter of 0.7 mm provided at a center position in the X direction. The target 45 has the marks 46 with diameters of 0.3 mm, 0.4 mm, 0.5 mm, 0.6 mm, 0.7 mm, 0.6 mm, 0.5 mm, 0.4 mm, and 0.3 mm with the center position as a reference.

Also, the target 45 has the marks 46 with a diameter of 0.7 mm provided at a center position in the Y direction. The target 45 has the marks 46 with diameters of 0.3 mm, 0.4 mm, 0.5 mm, 0.6 mm, 0.7 mm, 0.6 mm, 0.5 mm, 0.4 mm, and 0.3 mm with the center position as a reference.

Further, 0.4 mm marks 46 are provided in square frames at an M1 position. 0.5 mm marks 46 are provided in square frames at an M2 position. 0.6 mm marks 46 are provided in square frames at an M3 position. 0.7 mm marks 46 are provided in square frames at an M4 position.

Here, a center of the plurality of marks 46 coincide with a center of the target 45 and a center of the imaged portion 24. Therefore, hereinafter, the center of the plurality of marks 46 may be referred to as the center of the target 45.

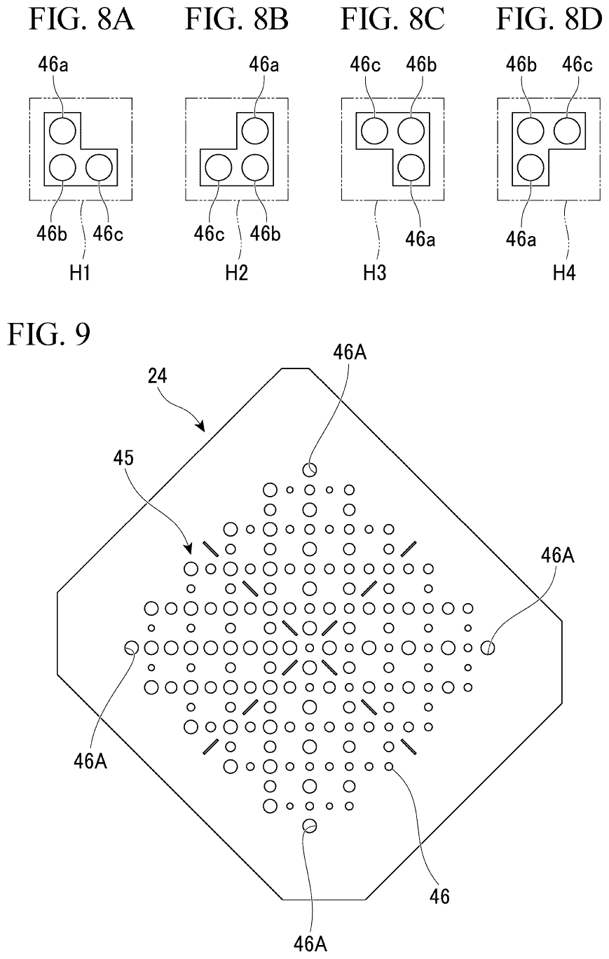

FIGS. 8(a) to 8(d) are conceptual views illustrating a minimum configuration for the imaging unit to capture an image in a single shot and determine a position.

As illustrated in FIGS. 6, 7, and 8(a) to 8(d), the plurality of marks 46 provided on the target 45 are disposed, for example, to be aligned in a row. Also, the plurality of marks 46 have holes whose shapes (sizes) are changed in stages. Here, the plurality of marks 46 are disposed so that at least three marks 46 can be imaged within imaging ranges H1, H2, H3, and H4 of the imaging unit 25 (see FIG. 1). The three marks 46 will be described as a mark 46a, a mark 46b, and a mark 46c. The marks 46a, 46b, and 46c can each be imaged by the imaging unit 25 in a single shot.

The mark 46a indicates X information. The mark 46b indicates the quadrant information. The mark 46c indicates Y information. The quadrant of the mark 46b is determined by the 0.4 mm mark 46 at the M1 position, the 0.5 mm mark 46 at the M2 position, the 0.6 mm mark 46 at the M3 position, and the 0.7 mm mark 46 at the M4 position.

Here, disposition patterns of the marks 46a, 46b, and 46c are shown in Table 1. The disposition patterns of the marks 46a, 46b, and 46c shown in Table 1 indicate all patterns in which the plurality of marks 46 provided on the target 45 can be imaged by the imaging unit 25 in a single shot. All the patterns that can be imaged are different from each other.

TABLE 1

| 46a | 46b | 46c | 46a | 46b | 46c | 46a | 46b | 46c | 46a | 46b | 46c |
|---|---|---|---|---|---|---|---|---|---|---|---|
| 3 | 4 | 7 | 3 | 4 | 7 | 3 | 4 | 6 | 3 | 4 | 7 |
| 4 | 4 | 6 | 3 | 7 | 6 | 3 | 4 | 7 | 4 | 4 | 6 |
| 4 | 4 | 7 | 4 | 4 | 6 | 4 | 4 | 5 | 4 | 4 | 7 |
| 4 | 7 | 6 | 4 | 4 | 7 | 4 | 4 | 6 | 4 | 7 | 6 |
| 5 | 4 | 5 | 4 | 7 | 6 | 4 | 4 | 7 | 5 | 4 | 5 |
| 5 | 4 | 6 | 4 | 7 | 5 | 4 | 7 | 6 | 5 | 4 | 6 |
| 5 | 4 | 7 | 5 | 4 | 5 | 5 | 4 | 4 | 5 | 4 | 7 |
| 5 | 7 | 6 | 5 | 4 | 6 | 5 | 4 | 5 | 5 | 7 | 6 |
| 5 | 7 | 5 | 5 | 4 | 7 | 5 | 4 | 6 | 5 | 7 | 5 |
| 6 | 4 | 4 | 5 | 7 | 6 | 5 | 4 | 7 | 6 | 4 | 4 |
| 6 | 4 | 5 | 5 | 7 | 5 | 5 | 7 | 6 | 6 | 4 | 5 |
| 6 | 4 | 6 | 5 | 7 | 4 | 5 | 7 | 5 | 6 | 4 | 6 |
| 6 | 4 | 7 | 6 | 4 | 4 | 6 | 4 | 3 | 6 | 4 | 7 |
| 6 | 7 | 6 | 6 | 4 | 5 | 6 | 4 | 4 | 6 | 7 | 6 |
| 6 | 7 | 5 | 6 | 4 | 6 | 6 | 4 | 5 | 6 | 7 | 5 |
| 6 | 7 | 4 | 6 | 4 | 7 | 6 | 4 | 6 | 6 | 7 | 4 |
| 7 | 4 | 3 | 6 | 7 | 6 | 6 | 4 | 7 | 7 | 4 | 3 |
| 7 | 4 | 4 | 6 | 7 | 5 | 6 | 7 | 6 | 7 | 4 | 4 |
| 7 | 4 | 5 | 6 | 7 | 4 | 6 | 7 | 5 | 7 | 4 | 5 |
| 7 | 4 | 6 | 6 | 7 | 3 | 6 | 7 | 4 | 7 | 4 | 6 |
| 7 | 4 | 7 | 7 | 4 | 3 | 7 | 4 | 3 | 7 | 4 | 7 |
| 7 | 7 | 6 | 7 | 4 | 4 | 7 | 4 | 4 | 7 | 7 | 6 |
| 7 | 7 | 5 | 7 | 4 | 5 | 7 | 4 | 5 | 7 | 7 | 5 |
| 7 | 7 | 4 | 7 | 4 | 6 | 7 | 4 | 6 | 7 | 7 | 4 |
| 7 | 7 | 3 | 7 | 4 | 7 | 7 | 4 | 7 | 7 | 7 | 3 |
| 6 | 5 | 4 | 7 | 7 | 6 | 7 | 7 | 6 | 6 | 5 | 3 |
| 6 | 5 | 5 | 7 | 7 | 5 | 7 | 7 | 5 | 6 | 5 | 4 |
| 6 | 5 | 6 | 7 | 7 | 4 | 7 | 7 | 4 | 6 | 5 | 5 |
| 6 | 5 | 7 | 7 | 7 | 3 | 7 | 7 | 3 | 6 | 5 | 6 |
| 6 | 6 | 6 | 6 | 5 | 4 | 6 | 5 | 4 | 6 | 5 | 7 |
| 6 | 6 | 5 | 6 | 5 | 5 | 6 | 5 | 5 | 6 | 6 | 6 |
| 6 | 6 | 4 | 6 | 5 | 6 | 6 | 5 | 6 | 6 | 6 | 5 |
| 6 | 6 | 3 | 6 | 5 | 7 | 6 | 5 | 7 | 6 | 6 | 4 |
| 5 | 5 | 5 | 6 | 6 | 6 | 6 | 6 | 6 | 5 | 5 | 4 |
| 5 | 5 | 6 | 6 | 6 | 5 | 6 | 6 | 5 | 5 | 5 | 5 |
| 5 | 5 | 7 | 6 | 6 | 4 | 6 | 6 | 4 | 5 | 5 | 6 |
| 5 | 6 | 6 | 5 | 5 | 5 | 5 | 5 | 5 | 5 | 5 | 7 |
| 5 | 6 | 5 | 5 | 5 | 6 | 5 | 5 | 6 | 5 | 6 | 6 |
| 5 | 6 | 4 | 5 | 5 | 7 | 5 | 5 | 7 | 5 | 6 | 5 |
| 4 | 5 | 6 | 5 | 6 | 6 | 5 | 6 | 6 | 4 | 5 | 5 |
| 4 | 5 | 7 | 5 | 6 | 5 | 5 | 6 | 5 | 4 | 5 | 6 |
| 4 | 6 | 6 | 4 | 5 | 6 | 4 | 5 | 6 | 4 | 5 | 7 |
| 4 | 6 | 5 | 4 | 5 | 7 | 4 | 5 | 7 | 4 | 6 | 6 |
| 3 | 5 | 7 | 4 | 6 | 6 | 4 | 6 | 6 | 3 | 5 | 6 |
| 3 | 6 | 6 | 3 | 5 | 7 | 3 | 5 | 7 | 3 | 5 | 7 |

Therefore, when the patterns of the marks 46a, 46b, and 46c shown in Table 1 are imaged from among the plurality of marks 46 provided on the target 45 with a single shot by the imaging unit 25, the position and angle T of the target 45 can be measured.

That is, with a disposition and shape of the plurality of marks 46 recorded in advance, the position and angle of the target 45 are calculated by comparing a disposition and shape of three imaged marks 46 with a disposition and shape of the pre-recorded marks 46. The X-Y position and angle T of the chuck 22 can be measured on the basis of the position and angle of the target 45. That is, the X-Y position and angle T of the chuck 22 can be measured on the basis of the marks 46 imaged in a single shot by the imaging unit 25 (see FIG. 1).

### <Chuck Position Measurement Method>

Next, a chuck position measurement method for measuring a position of the chuck 22 with the wafer inspection apparatus 10 will be described.

First, a chuck position measurement method according to the embodiment will be described.

As illustrated in FIG. 3, in the wafer inspection apparatus 10 of the embodiment, an example in which two targets 45 are provided on the chuck 22 has been described, but an example in which one target 45 is provided on the chuck 22 will be described in the chuck position measurement method of the embodiment.

FIG. 9 is a plan view illustrating an example in which a target is used for teaching.

As illustrated in FIGS. 1, 3, and 9, first, before the chuck position measurement method is performed, information necessary for the measurement is recorded by teaching. Specifically, the chuck 22 is detachably supported on the Z axis 18 (see FIG. 2) of the aligner 4. The supported chuck 22 is transferred to the probe card 21 of the head stage 12 by the aligner 4. In this state, X-Y-Z position coordinates and an angle T coordinate of the chuck 22 are recorded.

After the X-Y-Z position coordinates and angle T coordinate are recorded, the chuck 22 is transferred to (held by) the holding portion 23 while the X-Y-Z position coordinates and angle T coordinate are maintained. With the chuck 22 held by the holding portion 23, the marks 46 on the target 45 are imaged by the imaging unit 25, and X1-Y1-Z1 position coordinates at the center of the target 45 are recorded. Also, marks 46A at four corners of the plurality of marks 46 are detected. The angle TI coordinate at the center of the target 45 is recorded by detecting the marks 46A at the four corners. Thereby, the teaching is completed.

After teaching is performed, measurement for the chuck position is performed.

That is, with the chuck 22 held by the holding portion 23 when the chuck 22 is received by the aligner 4, the aligner 4 moves to the X1-Y1-Z1 coordinates, and the marks 46 are images (detected) in a single shot by the imaging unit 25.

The center coordinate and angular coordinate of the target 45 are measured on the basis of the disposition of the marks 46 imaged by the imaging unit 25.

A difference between the measured center coordinate and angle coordinate of the target 45, and the X1, Y1, and Z1 coordinates and angle TI coordinate of the target 45 obtained during the teaching is determined. The obtained difference is added to the transfer coordinates (the X-Y-Z position coordinates and angle T coordinate) obtained during teaching to determine a receiving coordinate of the chuck 22 (position and angle of the chuck) by the aligner 4. The aligner 4 moves to the receiving coordinate and receives the chuck 22.

According to the chuck position measurement method of the embodiment, the marks 46 provided on one target 45 are imaged in a single shot by the imaging unit 25, and thereby the receiving coordinate of the chuck 22 by the aligner 4 can be measured.

Here, when two targets 45 are provided on the chuck 22, an average of the center coordinate and angular coordinate of the two targets 45 is determined. Thereby, the receiving coordinate of the chuck 22 by the aligner 4 can be measured similarly to a case in which one target 45 is provided.

Next, a chuck position measurement method of a comparative example will be described.

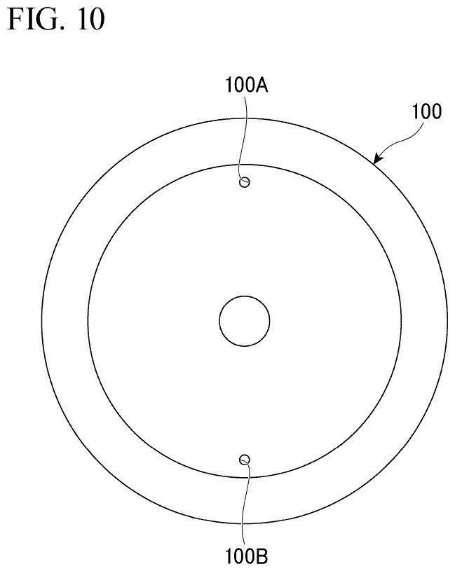

FIG. 10 is a rear view of a chuck of the comparative example from below.

As illustrated in FIG. 10, at least two marks, a first mark 100A and a second mark 100B are provided in a chuck 100 of the comparative example. The first mark 100A and the second mark 100B are small holes formed to have a diameter of, for example, 1.0 mm. The imaging range of the imaging unit 25 is relatively small, for example, about 3 mm×3 mm or 3 mm×4 mm.

As illustrated in FIGS. 1 and 10, first, before the chuck position measurement method is performed, information necessary for the measurement is recorded by teaching. Specifically, the chuck 100 is detachably supported on the Z axis 18 of the aligner 4. The held chuck 100 is transferred to the probe card 21 of the head stage 12 by the aligner 4. In this state, the X-Y-Z position coordinates and angle T coordinate of the chuck 100 are recorded.

After the X-Y-Z position coordinates and angle T coordinate are recorded, the chuck 100 is transferred to (held by) the holding portion 23 while the X-Y-Z position coordinates and angle T coordinate are maintained. With the chuck 100 held by the holding portion 23, the first mark 100A of the chuck 100 is imaged by the imaging unit 25, and the X1-Y1-Z1 position coordinates of the first mark 100A are recorded. Also, the second mark 100B of the chuck 100 is imaged by the imaging unit 25, and X2-Y2-Z2 coordinates of the second mark 100B are recorded. Thereby, the teaching is completed.

After teaching is performed, measurement for the chuck position is performed.

That is, when the chuck 100 is received by the aligner 4, the aligner 4 is moved to the X1-Y1-Z1 coordinates, and the first mark 100A is imaged (detected) by the imaging unit 25. If the first mark 100A is not within the imaging range of the imaging unit 25, the vicinity of the first mark 100A is scanned to image the first mark 100A. A difference between the position of the imaged first mark 100A and the X1-Y1-Z1 coordinates of the first mark 100A recorded during teaching is determined.

Also, the imaging unit 25 is moved to the X2-Y2-Z2 coordinates, and the second mark 100B is imaged (detected) by the imaging unit 25. If the second mark 100B is not within the imaging range of the imaging unit 25, the vicinity of the second mark 100B is scanned to image the second mark 100B. A difference between the position of the imaged second mark 100B and the X2-Y2-Z2 coordinates of the second mark 100B recorded during teaching is determined.

The difference in the X1-Y1-Z1 coordinates and the difference in the X2-Y2-Z2 coordinates correspond to an amount of displacement and an angular deviation of the chuck 100. The amount of displacement and the angular deviation of the chuck 100 are added to the transfer coordinates (X-Y-Z position coordinates and angle T coordinate) obtained during teaching, and measurement of a receiving coordinate of the chuck 100 by the aligner 4 is completed. The aligner 4 moves to the receiving coordinate to receive the chuck 100.

According to the chuck position measurement method of the comparative example, at least two marks, the first mark 100A and the second mark 100B, are imaged by the imaging unit 25. When the first mark 100A and the second mark 100B are misaligned, it is necessary to scan the first mark 100A and the second mark 100B while shifting the imaging position of the imaging unit 25. Therefore, it takes time for the imaging unit 25 to detect the first mark 100A and the second mark 100B.

According to the wafer inspection apparatus 10 and the chuck position measurement method described above, the target 45 was formed to be larger than the allowable movement range of the chuck 22 with respect to the holding portion 23 as illustrated in FIGS. 1, 3, and 5. Therefore, with the imaging unit 25 fixed at a predetermined position, the target 45 can be imaged in a single shot without being scanned by the imaging unit 25. The X-Y-Z position coordinates and angle T coordinate of the chuck 22 can be determined on the basis of the target 45 imaged by the imaging unit 25. Thereby, an improvement in throughput can be achieved.

Also, as illustrated in FIG. 5, the target 45 is provided on the imaged portion 24. The imaged portion 24 is a separate member from the chuck 22. Therefore, cost reduction can be achieved compared to, for example, when the target 45 is directly provided on the chuck 22.

Further, the target 45 has a plurality of marks 46. Therefore, when the disposition and shape of the plurality of marks 46 are set so that the X-Y-Z position coordinates and angle T coordinate of the chuck 22 can be measured, it is possible to determine the X-Y-Z position coordinates and angle T coordinate of the chuck 22 on the basis of the marks 46 imaged by the imaging unit 25 (see FIG. 1). Thereby, an improvement in throughput can be achieved.

Further, a reflectance of the imaged surface 24a was ensured in the imaged portion 24. Also, the black Mylar sheet 43 was provided on a side opposite to the imaged surface 24a. Therefore, the marks 46 can be reliably imaged by the imaging unit 25.

Also, according to the target 45 provided in the wafer inspection apparatus 10, the target 45 was formed to be larger than the allowable movement range of the chuck 22 with respect to the holding portion 23 (see FIG. 1) as illustrated in FIGS. 3, 6, and 7. Also, the target 45 had the plurality of marks 46, and the disposition and shape of the plurality of marks 46 were set so that the X-Y-Z position coordinates and angle T coordinate of the chuck 22 can be measured. Therefore, with the imaging unit 25 (see FIG. 1) fixed at a predetermined position, the target 45 can be imaged in a single shot without being scanned by the imaging unit 25. The X-Y-Z position coordinates and angle T coordinate of the chuck 22 can be determined on the basis of the marks 46 imaged by the imaging unit 25. Thereby, an improvement in throughput can be achieved.

### Modified Example

Next, modified examples 1 and 2 of the imaged portion 24 will be described.

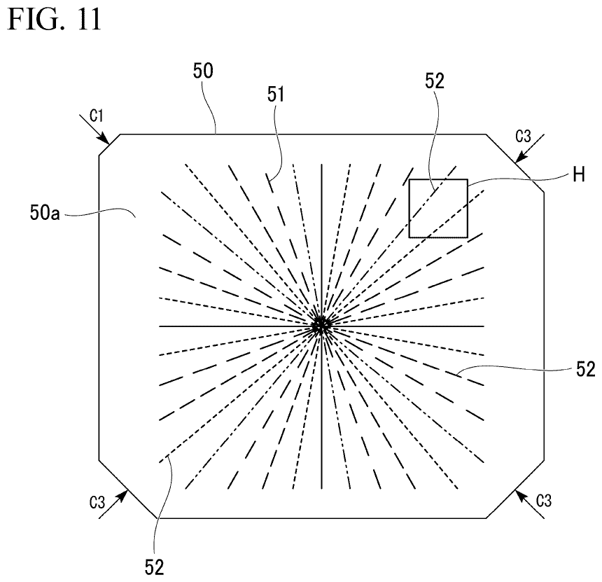

First, an imaged portion 50 of modified example 1 will be described with reference to FIG. 11.

FIG. 11 is a plan view illustrating an imaged portion of modified example 1.

As illustrated in FIG. 11, the imaged portion 50 of modified example 1 is formed of a translucent sheet material with a plate thickness of 0.3 mm similarly to the imaged portion 24 of the embodiment. A reflectance of an imaged surface 50a of the imaged portion 50 is ensured by, for example, electrolytic polishing.

The imaged portion 50 includes a target 51. The target 51 is formed to be larger than the allowable movement range of the chuck 22 (see FIG. 1). The target 51 has a plurality of marks 52. The plurality of marks 52 are formed in a pattern of straight lines of various types extending radially from a center of the target 51. Of the plurality of marks 52, the marks 52 necessary for measuring a position and angle of the chuck 22 can be imaged (detected) within the imaging range H in a single shot by the imaging unit 25 (see FIG. 1).

Thereby, when the marks 52 are imaged with the imaging unit 25, the X-Y-Z position coordinates and angle T coordinate of the chuck 22 (see FIG. 1) can be determined similarly to the imaged portion 24 of the embodiment, and the throughput can be improved.

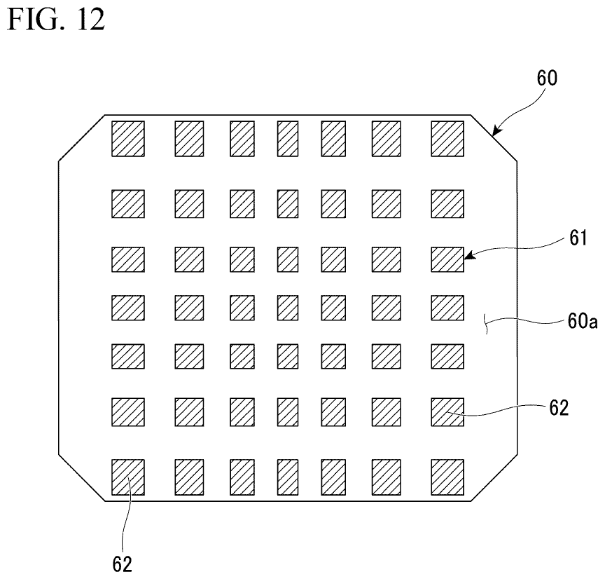

Next, an imaged portion 60 of modified example 2 will be described with reference to FIG. 12.

FIG. 12 is a plan view illustrating an imaged portion of modified example 2.

As illustrated in FIG. 12, the imaged portion 60 of modified example 2 is formed of a translucent sheet material with a plate thickness of 0.3 mm similarly to the imaged portion 24 of the embodiment. A reflectance of an imaged surface 60a of the imaged portion 60 is ensured by, for example, electrolytic polishing.

The imaged portion 60 includes a target 61. The target 61 is formed to be larger than the allowable movement range of the chuck 22 (see FIG. 1). The target 61 has a plurality of marks 62. The plurality of marks 62 are formed in a rectangular pattern by, for example, chrome deposition. Similarly to the marks 46 of the embodiment, a disposition and shape (size) of the plurality of marks 62 are set so that, for example, a position and angle of the chuck 22 can be measured. Of the plurality of marks 62, the marks 62 necessary for measuring the position and angle of the chuck 22 can be imaged (detected) in a single shot by the imaging unit 25 (see FIG. 1).

Thereby, when the mark 62 is imaged with the imaging unit 25, the X-Y-Z position coordinates and angle T coordinate of the chuck 22 (see FIG. 1) can be determined similarly to the imaged portion 24 of the embodiment, and the throughput can be improved.

Further, the technical scope of the present disclosure is not limited to the above-described embodiment, and various modifications can be made within a range not departing from the spirit of the present disclosure.

For example, in the above-described embodiment, modified example 1, and modified example 2, an example in which the marks of the target are formed as a circle, a straight line, and a rectangle has been described, but the present disclosure is not limited thereto. As another example, the mark may be formed in a pattern such as letters, numbers, or symbols.

In addition, the components in the above-described embodiment can be appropriately replaced with well-known components within a range not departing from the spirit of the present disclosure. While preferred embodiments of the invention have been described and illustrated above, it should be understood that these are exemplary of the invention and are not to be considered as limiting. Additions, omissions, substitutions, and other modifications can be made without departing from the spirit or scope of the present disclosure. Accordingly, the invention is not to be considered as being limited by the foregoing description, and is only limited by the scope of the appended claims.

### EXPLANATION OF REFERENCES

10 Wafer inspection apparatus
12 Head stage
21 Probe card
22 Chuck
23 Holding portion
24, 50, 60 Imaged portion
24a, 50a, 60a Imaged surface
25 Imaging unit
43 Mylar sheet
45, 51, 61 Target
46, 52, 62 Mark
W Wafer

What is claimed is:

1. A wafer inspection apparatus comprising:
a probe card provided on a head stage;
a chuck holding a wafer and being able to electrically connect the wafer to the probe card;
a holding portion provided below the head stage and holding the chuck;
a target provided on the chuck; and
an imaging unit imaging the target, wherein
the target is formed to be larger than an allowable movement range of the chuck with respect to the holding portion to be able to be imaged by the imaging unit with the imaging unit fixed at a predetermined position, and
a position and angle of the chuck are determined on the basis of the target imaged by the imaging unit.

2. The wafer inspection apparatus according to claim 1, wherein the target is provided on an imaged portion formed of a sheet material which is a separate member from the chuck, and has a plurality of marks having holes with diameters of 0.3 to 7 mm at a pitch of 1 mm.

3. The wafer inspection apparatus according to claim 2, wherein the imaged portion has an ensured reflectance on an imaged surface and is provided with a black Mylar sheet on a side opposite to the imaged surface.

4. A chuck position measurement method, which is a chuck position measurement method in which a chuck is held by a holding portion, and a target provided on the chuck is imaged by the imaging unit,
the chuck position measurement method comprising:
imaging the target, which is formed to be larger than an allowable movement range of the chuck with respect to the holding portion, in a single shot with the imaging unit fixed at a predetermined position; and
determining a position and an angle of the chuck on the basis of the target imaged by the imaging unit.

5. A target, which is a target imaged by an imaging unit to determine a position and an angle of a chuck held by a holding portion, with the chuck held by the holding portion,
formed to be larger than an allowable movement range of the chuck with respect to the holding portion to be able to be imaged by the imaging unit with the imaging unit fixed at a predetermined position, and
having a plurality of marks whose disposition and shape are set to be able to measure a position and an angle of the chuck.
